(19) United States
(12) Patent Application Publication
(10) Pub. No.: US 2024/0292671 A1
(43) Pub. Date: Aug. 29, 2024

(54) DISPLAY DEVICE

(71) Applicant: LG Display Co., Ltd., Seoul (KR)

(72) Inventors: Tae-Gwan LEE, Paju-si (KR); Hong-Jae SHIN, Paju-si (KR); Yong-Ho KIM, Paju-si (KR)

(21) Appl. No.: 18/586,442

(22) Filed: Feb. 24, 2024

(30) Foreign Application Priority Data
Feb. 28, 2023 (KR) 10-2023-0026631

(51) Int. Cl. H10K 59/122; H10K 59/124

(52) U.S. Cl. CPC H10K 59/122; H10K 59/124

(57) ABSTRACT

A display device includes: a substrate having a display area including a subpixel and a non-display area surrounding the display area; a driving transistor and a light emitting diode in the subpixel on the substrate; an overcoat layer between driving transistor and the light emitting diode; and a bank layer on the overcoat layer, wherein in the non-display area, parts of the overcoat layer and the bank layer are removed to form at least one trench.

### CROSS-REFERENCE TO RELATED APPLICATION

The present application claims the benefit of Republic of Korea Patent Application No. 10-2023-0026631, filed on Feb. 28, 2023, which is hereby incorporated by reference in its entirety.

### BACKGROUND

### Technical Field

The present disclosure relates to a display device, and more particularly, to a display device where a penetration of a moisture is reduced or minimized due to a trench of an overcoat layer in a non-display area.

### Discussion of the Related Art

Recently, with the advent of an information-oriented society, the interest in information displays for processing and displaying a massive amount of information and the demand for portable information media have increased. As such, a display field has rapidly advanced. Thus, various light and thin flat panel display devices have been developed and highlighted.

Among the various flat panel display devices, an organic light emitting diode (OLED) display device is an emissive type device that does not include a backlight unit used in a non-emissive type device such as a liquid crystal display (LCD) device. As a result, the OLED display device has advantages in a viewing angle, a contrast ratio and a power consumption to be applied to various fields.

In the OLED display device, since an external moisture permeates into a light emitting diode in a display area through an interface between an overcoat layer and a bank layer in a non-display area, the light emitting diode is deteriorated and a display quality of an image is deteriorated.

### SUMMARY

Accordingly, the present disclosure is directed to a display device that substantially obviates one or more of the problems due to limitations and disadvantages of the related art.

An object of the present disclosure is to provide a display device where a permeation of an external moisture into a light emitting diode in a display area is reduced and minimized by forming a trench in an overcoat layer and a bank layer in a non-display area.

Another object of the present disclosure is to provide a display device where a permeation of a moisture through an interface between an overcoat layer and a bank layer is reduced and minimized without a loss of an aperture ratio and a deterioration of a property of a light emitting diode and a property of a display quality of an image by forming a trench in an overcoat layer and a bank layer in a non-display area.

Additional features and advantages of the disclosure will be set forth in the description which follows, and in part will be apparent from the description, or can be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display device includes: a substrate having a display area including a subpixel and a non-display area surrounding the display area; a driving transistor and a light emitting diode in the subpixel on the substrate; an overcoat layer between driving transistor and the light emitting diode; and a bank layer on the overcoat layer, wherein the overcoat layer and the bank layer have at least one trench in the non-display area.

It is to be understood that both the foregoing general description and the following detailed description are explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a view showing a display device according to an embodiment of the present disclosure;

FIG. 2 is block diagram showing first and second gate driving units and a display panel of a display device according to an embodiment of the present disclosure;

FIG. 3 is a circuit diagram showing a subpixel of a display device according to an embodiment of the present disclosure;

FIG. 4 is a circuit diagram showing a subpixel of a 3TIC structure of a display device according to an embodiment of the present disclosure;

FIG. 5 is a cross-sectional view showing a subpixel of a display device according to an embodiment of the present disclosure;

FIG. 6 is a plan view showing a display device according to an embodiment of the present disclosure;

FIGS. 7A and 7B are magnified views showing portions A and B, respectively, of FIG. 6, according to an embodiment of the present disclosure; and

FIGS. 8A and 8B are cross-sectional views taken along a line VIIIa-VIIIa and a line VIIIb-VIIIb, respectively, of FIG. 7A, according to an embodiment of the present disclosure.

### DETAILED DESCRIPTION

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure. Further, the present disclosure is only defined by scopes of claims.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. Like reference numerals refer to like elements throughout the specification, unless otherwise specified.

In the following description, where the detailed description of the relevant known function or configuration may unnecessarily obscure a feature or aspect of the present disclosure, a detailed description of such known function or configuration may be omitted or a brief description may be provided.

Where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween.

Although the terms “first,” “second,” A, B, (a), (b), and the like may be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the present disclosure.

The term “at least one” should be understood to include all combinations of one or more of related elements. For example, the term of “at least one of first, second and third elements” may include all combinations of two or more of the first, second and third elements as well as the first, second or third element.

The term “display device” may include a display device in a narrow sense such as liquid crystal module (LCM), an organic light emitting diode (OLED) module and a quantum dot (QD) module including a display panel and a driving unit for driving the display panel. In addition, the term “display device” may include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure may include an applied product or a set device of a final user's device including the LCM, the OLED module and the QD module as well as a display device in a narrow sense such as the LCM, the OLED module and the QD module.

According to circumstances, the LCM, the OLED module and the QD module having a display panel and a driving unit may be expressed as “a display device”, and an electronic apparatus of a complete product including the LCM, the OLED module and the QD module may be expressed as “a set device.” For example, a display device in a narrow sense may include a display panel of a liquid crystal, an organic light emitting diode and a quantum dot and a source printed circuit board (PCB) of a control unit for driving the display panel, and a set device may further include a set PCB of a set control unit electrically connected to the source PCB for controlling the entire set device.

The display panel of the present disclosure may include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel may include a plurality of gate lines, a plurality of data lines and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of moisture or oxygen into the emitting element layer. In addition, a layer on the array may include an inorganic light emitting layer, for example, a nano-sized material layer or a quantum dot.

The thin film transistor of the present disclosure may include one of an oxide thin film transistor, an amorphous silicon thin film transistor, a low temperature polycrystalline silicon thin film transistor.

Features of various embodiments of the present disclosure may be partially or entirely coupled to or combined with each other. They may be linked and operated technically in various ways as those skilled in the art can sufficiently understand. The embodiments may be carried out independently of or in association with each other in various combinations.

Hereinafter, a display device according to various example embodiments of the present disclosure where an influence on an oxide semiconductor layer of a thin film transistor of a driving element part is reduced by shielding a light emitted and transmitted from a subpixel and/or a light inputted from an exterior will be described in detail with reference to the accompanying drawings.

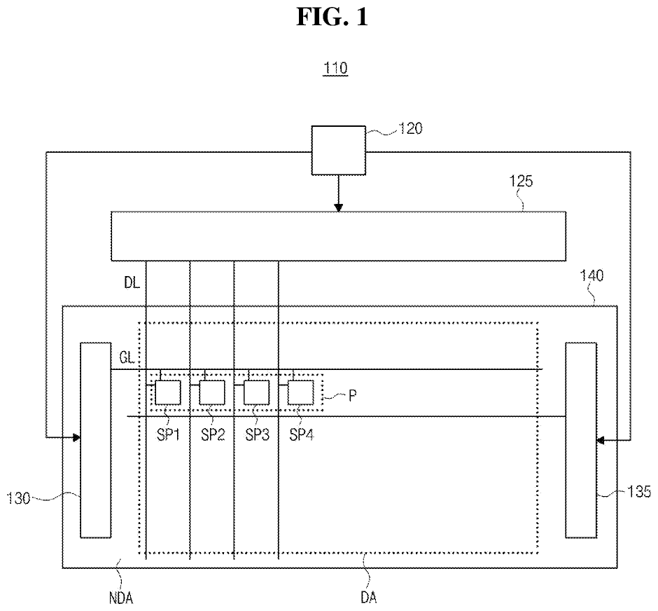

FIG. 1 is a view showing a display device according to an embodiment of the present disclosure. The display device may be an organic light emitting diode (OLED) display device.

In FIG. 1, a display device 110 according to an embodiment of the present disclosure includes a timing controlling unit 120, a data driving unit 125, first and second gate driving units 130 and 135 and a display panel 140.

The timing controlling unit 120 (e.g., a circuit) generates an image data, a data control signal and a gate control signal using an image signal and a plurality of timing signals including a data enable signal, a horizontal synchronization signal, a vertical synchronization signal and a clock signal transmitted from an external system such as a graphic card or a television system. The image data and the data control signal are transmitted to the data driving unit 125, and the gate control signal is transmitted to the first and second gate driving units 130 and 135.

The data driving unit 125 (e.g., a circuit) generates a data signal (a data voltage) Vdata (of FIG. 3) using the data control signal and the image data transmitted from the timing controlling unit 120 and transmits the data signal to a data line DL of the display panel 140.

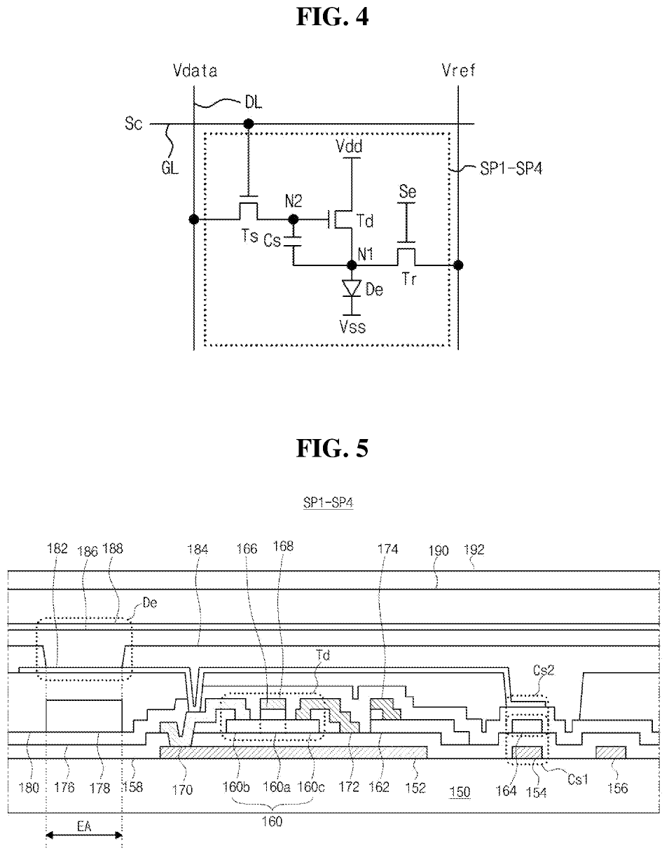

The first and second gate driving units 130 and 135 (e.g., circuits) generate a gate signal (a gate voltage) using the gate control signal transmitted from the timing controlling unit 120 and applies the gate signal to a gate line GL of the display panel 140. For example, the gate signal may include a scan signal Sc (of FIG. 4), a sensing signal Se (of FIG. 4) and an emission signal.

The first and second gate driving units 130 and 135 may be a gate in panel (GIP) type formed in a non-display area NDA of a substrate of the display panel 140 having the gate line GL, the data line DL and a pixel P.

Although the first and second gate driving units 130 and 135 are disposed in both side portions of the display panel 140 in the embodiment of FIG. 1, one gate driving unit may be disposed in one side portion of the display panel 140 in another embodiment.

The display panel 140 includes a display area DA at a central portion thereof and a non-display area NDA adjacent to and surrounding the display area DA. The display panel 140 displays an image using the gate signal and the data signal Vdata. For displaying an image, the display panel 140 includes a plurality of pixels P, a plurality of gate lines GL and a plurality of data lines DL in the display area DA.

Each of the plurality of pixels P includes first, second, third and fourth subpixels SP1, SP2, SP3 and SP4, and the gate line GL and the data line DL cross each other to define the first, second, third and fourth subpixels SP1, SP2, SP3 and SP4. Each of the first, second, third and fourth subpixels SP1, SP2, SP3 and SP4 is connected to the gate line GL and the data line DL. For example, the first, second, third and fourth subpixels SP1, SP2, SP3 and SP4 may correspond to red, green, blue and white, respectively.

When the display device 110 is an OLED display device, each of the first, second, third and fourth subpixels SP1, SP2, SP3 and SP4 may include a plurality of transistors such as a switching transistor Ts (of FIG. 4), a driving transistor Td (of FIG. 4) and a reference transistor Tr (of FIG. 4), a storage capacitor Cs (of FIG. 4) and a light emitting diode De (of FIG. 4).

A structure and an operation of the first and second gate driving units 130 and 135 and the first, second, third and fourth subpixels SP1, SP2, SP3 and SP4 of the display device 110 will be illustrated with reference to a drawing.

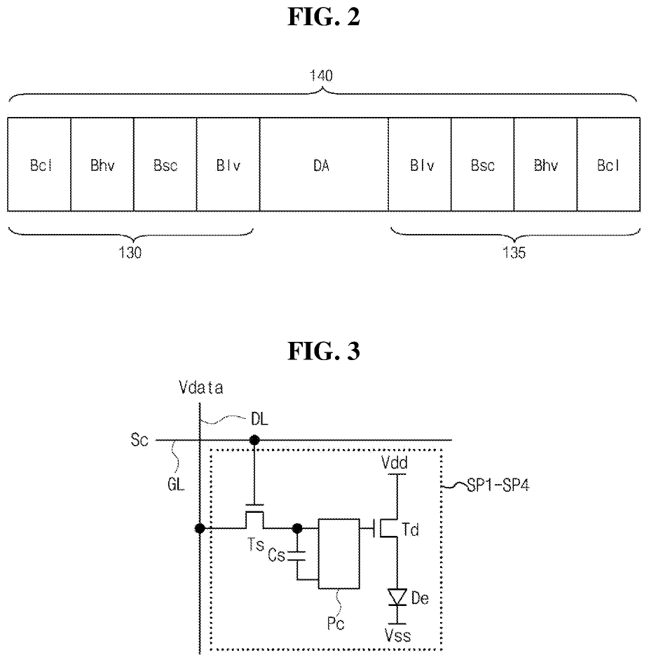

FIG. 2 is block diagram showing first and second gate driving units and a display panel of a display device according to an embodiment of the present disclosure, and FIG. 3 is a circuit diagram showing a subpixel of a display device according to an embodiment of the present disclosure. The display device 110 may be an organic light emitting diode (OLED) display device.

In FIG. 2, each of the first and second gate driving units 130 and 135 of the display device 110 according to an embodiment of the present disclosure includes a clock signal block Bcl (e.g., a circuit), a high level voltage block Bhv (e.g., a circuit), a stage circuit block Bsc (e.g., a circuit) and a low level voltage block Blv (e.g., a circuit), and the display area DA is disposed between the first and second gate driving units 130 and 135.

In another embodiment, the disposition structure of the clock signal block Bcl, the high-level voltage block Bhv, the stage circuit block Bsc and the low-level voltage block Blv in the first and second gate driving units 130 and 135 may be variously changed.

Each of the first and second gate driving units 130 and 135 may include a shift register including a plurality of stages connected to each other in a cascade type.

The clock signal block Bcl includes a plurality of clock lines transmitting a clock signal used in the stage circuit block Bsc.

For example, the clock signal may include a carry clock transmitted between one stage and another stage of the shift register, a scan clock used for generation of the scan signal Sc of the gate signal supplied to the display area DA of the display panel 140 and a sensing clock used for generation of the sensing signal Se of the gate signal supplied to the display area DA of the display panel 140.

The clock signal block Bcl may include a carry clock block including the clock line transmitting the carry clock, a scan clock block including the clock line transmitting the scan clock and a sensing clock block including the clock line transmitting the sensing clock.

The high-level voltage block Bhv includes a plurality of power lines transmitting the high-level voltage and the control signal of the first and second gate driving units 130 and 135.

For example, the high level voltage of the first and second gate driving units 130 and 135 may include a high level voltage for a shift register and a high level voltage for an inverter of each stage, and the control signal of the first and second gate driving units 130 and 135 may include a start signal corresponding to an operation start of a first stage, a reset signal corresponding to an operation end of a last stage and a real time signal used for generation of a compensation signal in an operation for a real time compensation.

The stage circuit block Bsc as one stage of the shift register generates and outputs the gate signal including the carry signal, the scan signal Sc and the sensing signal Se. The carry signal is transmitted to the other stage, and the scan signal Sc and the sensing signal Se are transmitted to the display area DA.

For example, the stage circuit block Bsc may include a compensation block for an operation of a real time operation, a carry block including a line transmitting the carry signal to the other stage, a logic block substantially generating a plurality of output signals and a buffer block outputting the scan signal Sc and the sensing signal Se of the gate signal supplied to the display area DA of the display panel 140.

The stage circuit block Bsc may include a plurality of transistors and a plurality of capacitors.

The low-level voltage block Blv includes the plurality of power lines transmitting the low-level voltage of the first and second gate driving units 130 and 135.

In the first and second gate driving units 130 and 135, the stage block Bsc generates the carry signal, the scan signal Sc and the sensing signal Se using the carry clock, the scan clock and the sensing clock transmitted from the clock signal block Bcl. The carry signal is transmitted to the other stage circuit block Bsc, and the scan signal Sc and the sensing signal Se are transmitted to each subpixel SP1, SP2, SP3 and SP4 of the display area DA.

In FIG. 3, each of the first, second, third and fourth subpixels SP1, SP2, SP3 and SP4 of the display panel 140 of the display device 110 according to an embodiment of the present disclosure includes a switching transistor Ts, a driving transistor Td, a compensation part Pc, a storage capacitor Cs and a light emitting diode De. The switching transistor Ts and the driving transistor Td may be an oxide semiconductor thin film transistor or a low temperature polycrystalline silicon thin film transistor.

The switching transistor Ts is switched according to the scan signal Sc of the gate signal. A gate electrode of the switching transistor Ts is connected to the scan signal Sc, a source electrode of the switching transistor Ts is connected to a first capacitor electrode of the storage capacitor Cs and the compensation part Pc, and a drain electrode of the switching transistor Ts is connected to the data signal Vdata.

The driving transistor Td is switched according to a voltage of the compensation part Pc. A gate electrode of the driving transistor Td is connected to the compensation part Pc, a source electrode of the driving transistor Td is connected to an anode of the light emitting diode De, and a drain electrode of the driving transistor Td is connected to the high-level voltage Vdd.

The compensation part Pc is connected among the switching transistor Ts, the driving transistor Td and the storage capacitor Cs and compensates a variation of the threshold voltage Vth of the driving transistor Td.

The storage capacitor Cs stores the data signal Vdata. A first capacitor electrode of the storage capacitor Cs is connected to the source electrode of the switching transistor Ts and the compensation part Pc, and a second capacitor electrode of the storage capacitor Cs is connected to the compensation part Pc.

The light emitting diode De is connected between the driving transistor Td and the low-level voltage Vss and emits a light of a luminance proportional to a current of the driving transistor Td. An anode of the light emitting diode De is connected to the source electrode of the driving transistor Td, and a cathode of the light emitting diode De is connected to the low-level voltage Vss.

The data signal Vdata is supplied from the data driving unit 125 to each subpixel SP1, SP2, SP3 and SP4 of the display panel 140, and the scan signal Sc of the gate signal is supplied from the first and second gate driving units 130 and 135 to each subpixel SP1, SP2, SP3 and SP4 of the display panel 140.

Each of the first, second, third and fourth subpixels SP1, SP2, SP3 and SP4 may have one of 3T1C structure including three transistors and one capacitor, 6T1C structure including six transistors and one capacitor, 7T1C structure including seven transistors and one capacitor and 8TIC structure including eight transistors and one capacitor.

A 3T1C structure of each subpixel SP1, SP2, SP3 and SP4 will be illustrated with reference to a drawing.

FIG. 4 is a circuit diagram showing a subpixel of a 3T1C structure of a display device according to an embodiment of the present disclosure.

In FIG. 4, each of the first, second, third and fourth subpixels SP1, SP2, SP3 and SP4 of the display panel 140 of the display device 110 according to an embodiment of the present disclosure includes a switching transistor Ts, a driving transistor Td, a reference transistor Tr, a storage capacitor Cs and a light emitting diode De. The switching transistor Ts, the driving transistor Td and the reference transistor Tr may be an oxide semiconductor thin film transistor or a low temperature polycrystalline silicon thin film transistor.

The switching transistor Ts is switched according to a scan signal Sc of the gate signal. A gate electrode of the switching transistor Ts is connected to the scan signal Sc, a source electrode of the switching transistor Ts is connected to a first capacitor electrode of the storage capacitor Cs and a gate electrode of the driving transistor Td, and a drain electrode of the switching transistor Ts is connected to the data signal Vdata.

The driving transistor Td is switched according to a voltage of the first capacitor electrode of the storage capacitor Cs. A gate electrode of the driving transistor is connected to the source electrode of the switching transistor Ts and the first capacitor electrode of the storage capacitor Cs, a source electrode of the driving transistor Td is connected to a second capacitor electrode of the storage capacitor Cs, an anode of the light emitting diode De and a source electrode of the reference transistor Tr, and a drain electrode of the driving transistor Td is connected to the high level voltage Vdd.

The storage capacitor Cs stores the data signal Vdata compensated with a threshold voltage Vth of the driving transistor Td. The first capacitor electrode of the storage capacitor Cs is connected to the source electrode of the switching transistor Ts and the gate electrode of the driving transistor Td, and the second capacitor electrode of the storage capacitor Cs is connected to the source electrode of the driving transistor Td, the source electrode of the reference transistor Tr and the anode of the light emitting diode De.

The light emitting diode De is connected between the driving transistor Td and the low-level voltage Vss and emits a light of a luminance proportional to a current of the driving transistor Td. The anode of the light emitting diode De is connected to the source electrode of the driving transistor Td, the second capacitor electrode of the storage capacitor Cs and the source electrode of the reference transistor Tr, and a cathode of the light emitting diode De is connected to the low-level voltage Vss.

The data signal Vdata and the reference signal Vref are supplied from the data driving unit 125 to each subpixel SP1 to SP4 of the display panel 140, and the scan signal Sc and the sensing signal Se of the gate signal are supplied from the first and second gate driving units 130 and 135 to each subpixel SP1 to SP4 of the display panel 140.

The source electrode of the driving transistor Td, the source electrode of the reference transistor Tr, the second capacitor electrode of the storage capacitor Cs and the anode of the light emitting diode De are connected to each other to constitute a first node N1, and the gate electrode of the driving transistor Td, the source electrode of the switching transistor Ts and the first capacitor electrode of the storage capacitor Cs are connected to each other to constitute a second node N2.

In the display device 110, during an initialization period where the reference transistor Tr is turned on, the reference signal Vref is supplied to the first node N1 and the first and second nodes N1 and N2 are initialized. During a writing period where the switching transistor Ts is turned on and off, the data signal Vdata is applied to the second node N2 and the threshold voltage of the driving transistor Td is stored in the storage capacitor Cs. During a sensing period where the reference transistor Tr is turned on again, the data driving unit 125 detects the threshold voltage of the driving transistor Td stored in the storage capacitor Cs and transmits the threshold voltage to the timing controlling unit 120.

Next, the timing controlling unit 120 modifies the data signal Vdata to generate a compensated data signal where the threshold voltage is compensated and supply the compensated data signal to each subpixel SP1 to SP4 through the data driving unit 125. During an emission period where the switching transistor Ts is turned on, a current corresponding to the compensated data signal is supplied to the light emitting diode De through the driving transistor Td and the light emitting diode De emits a light.

A cross-sectional structure of each subpixel will be illustrated with reference to a drawing.

FIG. 5 is a cross-sectional view showing a subpixel of a display device according to an embodiment of the present disclosure.

In FIG. 5, each subpixel SP1 to SP4 of the display device 110 according to an embodiment of the present disclosure includes the driving transistor Td and the light emitting diode De.

A light shielding layer 152, a first capacitor pattern 154 and a data line 156 are disposed on a substrate 150.

The substrate 150 may include a glass or a multiple layer where an organic layer and an inorganic layer are alternately laminated. For example, the substrate 150 may include an organic insulating material layer such as polyimide (PI) and an inorganic insulating material layer such as silicon oxide (SiO2) alternately laminated.

The light shielding layer 152, the first capacitor pattern 154 and the data line 156 may have the same layer and the same material as each other through a single mask process. The light shielding layer 152, the first capacitor pattern 154 and the data line 156 may include a metallic material.

For example, the light shielding layer 152, the first capacitor pattern 154 and the data line 156 may have a single layer or multiple layers including one of molybdenum (Mo), aluminum (Al), chromium (Cr), gold (Au), titanium (Ti), nickel (Ni), neodymium (Nd), copper (Cu) and an alloy thereof.

A buffer layer 158 is disposed on the light shielding layer 152, the first capacitor pattern 154 and the data line 156 over the entire substrate 150. The buffer layer 158 may block a moisture penetrable from an exterior. For example, the buffer layer 158 may have a multiple layer of an inorganic material such as silicon oxide (SiO2).

An active layer 160 and a semiconductor layer 162 are disposed on the buffer layer 158 corresponding to the light shielding layer 152, and a second capacitor pattern 164 is disposed on the buffer layer 158 corresponding to the first capacitor pattern 154.

The active layer 160, the semiconductor layer 162 and the second capacitor pattern 164 may have the same layer and the same material as each other through a single mask process. The active layer 160, the semiconductor layer 162 and the second capacitor pattern 164 may include polycrystalline silicon or oxide semiconductor material.

The active layer 160 may have a channel region 160a at a central portion thereof and source and drain regions 160b and 160c at both side portions of the channel region 160a. The channel region 160a may include an intrinsic semiconductor material without an impurity, and the source and drain regions 160b and 160c may include an impurity doped semiconductor material.

The first capacitor pattern 154, the buffer layer 158 and the second capacitor pattern 164 constitute a first storage capacitor Cs1.

A patterned gate insulating layer 166 is disposed on the channel region 160a, the source region 160b and the drain region 160c of the active layer 160 and the semiconductor layer 162. The gate insulating layer 166 may have a single layer or a multiple layer of an inorganic insulating material such as silicon oxide (SiO2) and silicon nitride (SiNx).

A gate electrode 168, a source electrode 170 and a drain electrode 172 are disposed on the gate insulating layer 166 corresponding to the channel region 160a, the source region 160b and the drain region 160c, respectively, of the active layer 160, and a gate line 174 is disposed on the gate insulating layer 166 corresponding to the semiconductor layer 162.

The gate electrode 168, the source electrode 170, the drain electrode 172 and the gate line 174 may have the same layer and the same material as each other through a single mask process. The gate electrode 168, the source electrode 170, the drain electrode 172 and the gate line 174 may include a metallic material.

For example, the gate electrode 168, the source electrode 170, the drain electrode 172 and the gate line 174 may have a single layer or multiple layers including one of molybdenum (Mo), aluminum (Al), chromium (Cr), gold (Au), titanium (Ti), nickel (Ni), neodymium (Nd), copper (Cu) and an alloy thereof.

The gate electrode 168 does not contact the channel region 160a of the active layer 160. On the other hand, the source electrode 170 contacts the light shielding layer 152 through a contact hole of the buffer layer 158 and the source region 160b of the active layer 160 through a side surface of the gate insulating layer 166. Further, the drain electrode 172 contacts the drain region 160c of the active layer 160 through the side surface of the gate insulating layer 166, and the gate line 174 contacts the semiconductor layer 162 through the side surface of the gate insulating layer 166.

In another embodiment, an additional metal layer may be disposed between the active layer 160 and the source electrode 170 and between the active layer 160 and the drain electrode 172. The metal layer may be formed simultaneously with the active layer 160 through a photolithographic process using a half transmissive mask.

The active layer 160, the gate insulating layer 166, the gate electrode 168, the source electrode 170 and the drain electrode 172 constitute the driving transistor Td.

An interlayer insulating layer 176 is disposed on the gate electrode 168, the source electrode 170, the drain electrode 172, the gate line 174 and the second capacitor pattern 164 over the entire substrate 150. The interlayer insulating layer 176 may have a single layer or a multiple layer of an inorganic insulating material such as silicon oxide (SiO2) and silicon nitride (SiNx).

A color filter layer 178 is disposed in an emission area EA on the interlayer insulating layer 176. For example, the color filter layer 178 of the first, second, third and fourth subpixels SP1, SP2, SP3 and SP4 may correspond to red, green, blue and white colors, respectively.

An overcoat layer 180 is disposed on the color filter layer 178 over the entire substrate 150. The overcoat layer 180 may include an organic insulating material such as polyimide (PI) and acrylic resin.

A first electrode 182 is disposed on the overcoat layer 180 and is connected to the source electrode 170 through a contact hole in the overcoat layer 180 and the interlayer insulating layer 176. The first electrode 182 may be an anode of a multiple layer including a transparent conductive material.

For example, the transparent conductive material may include a material having a relatively high work function such as indium tin oxide (ITO) and indium zinc oxide (IZO).

The first electrode 182 extends from the emission area EA to overlap the second capacitor pattern 164. The second capacitor pattern 164, the interlayer insulating layer 176 and the first electrode 182 constitute a second storage capacitor Cs2.

The first and second storage capacitors Cs1 and Cs2 are connected to each other in parallel to constitute the storage capacitor Cs (of FIG. 3).

A bank layer 184 is disposed on the first electrode 182 to cover an edge portion of the first electrode 182. The bank layer 184 has an opening exposing a central portion of the first electrode 182, and the opening of the bank layer 184 corresponds to the emission area EA.

For example, the bank layer 184 may include an opaque material (e.g. black material) to prevent light interference between the adjacent subpixels SP1 to SP4. The bank layer 184 may include a shielding material of at least one of a color pigment, an organic black and a carbon.

Although not shown, a spacer may be disposed on the bank layer 184.

An emitting layer 186 is disposed on the bank layer 184 and the first electrode 182 exposed through the opening of the bank layer 184. The emitting layer 186 may include a hole relating layer, an organic emitting layer and an electron relating layer sequentially or reversely laminated.

For example, the emitting layer 186 may include a hole injecting layer, a hole transporting layer, an emitting material layer, an electron transporting layer and an electron injecting layer.

A second electrode 188 is disposed on the emitting layer 186 over the entire substrate 150. The second electrode 188 may be a cathode of a multiple layer including an opaque conductive material having a relatively high reflection efficiency.

For example, the opaque conductive material may include a material having a relatively low work function such as aluminum (Al), silver (Ag), copper (Cu), lead (Pb), molybdenum (Mo), titanium (Ti) and an alloy thereof.

The first electrode 182, the emitting layer 186 and the second electrode 188 constitute the light emitting diode De.

Although the display device 110 has a bottom emission type where the first electrode 182 includes a transparent material and the second electrode 188 has an opaque material having a relatively high reflectance in an embodiment of FIG. 5, the display device 110 may have a top emission type where the first electrode 182 includes an opaque material having a relatively high reflectance and the second electrode 188 includes a transparent material and the color filter layer 178 is disposed on the second electrode 188 in another embodiment.

A first encapsulating layer 190 and a second encapsulating layer 192 are sequentially disposed on the second electrode 188 over the entire substrate 150. The first encapsulating layer 190 and the second encapsulating layer 192 may prevent a moisture or an oxygen of an exterior from permeating the light emitting diode De.

For example, the first encapsulating layer 190 may include a non-photosensitive organic insulating material such as acrylic resin, epoxy resin, phenolic resin, polyamide resin, polyimide resin, polyethylene and silicon oxycarbon (SiOC) or a photosensitive organic insulating material such as photoacryl, and the second encapsulating layer 192 may include a metallic material.

In the display device 110, a trench is formed in the overcoat layer 180 and the bank layer 184 of the non-display area NDA.

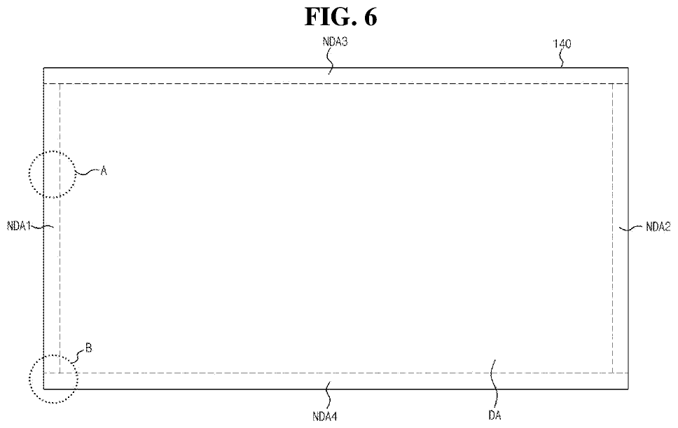

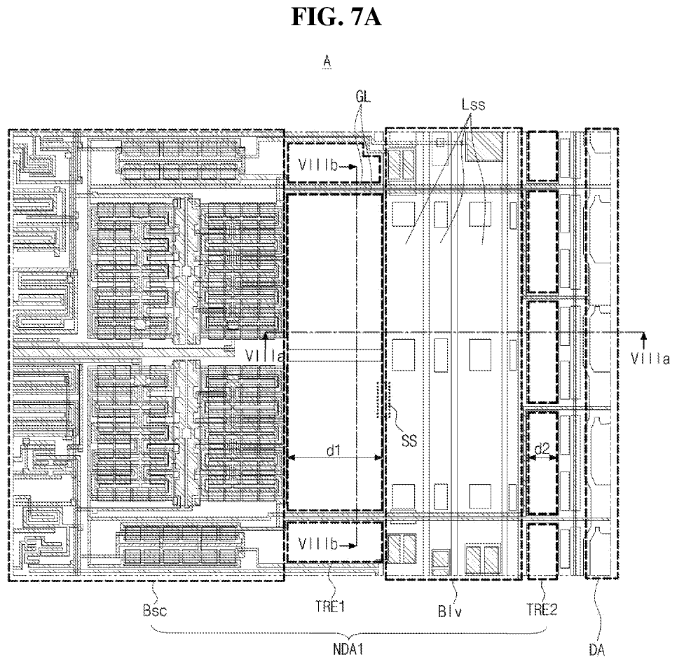

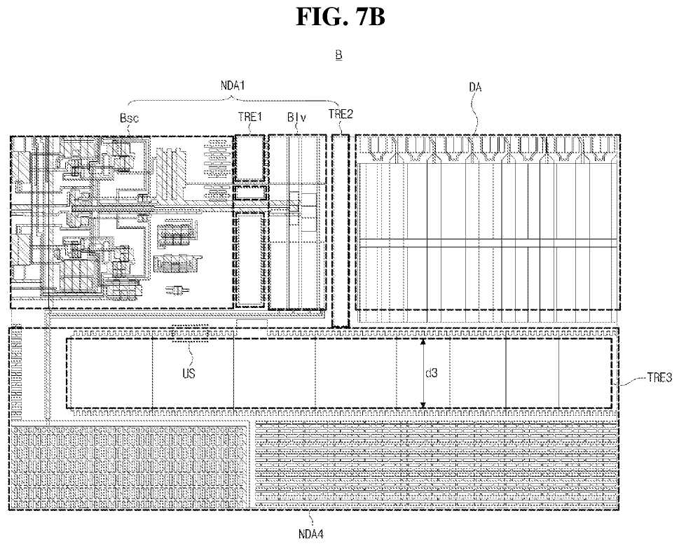

FIG. 6 is a plan view showing a display device according to an embodiment of the present disclosure, and FIGS. 7A and 7B are magnified views showing portions A and B, respectively, of FIG. 6, according to an embodiment of the present disclosure.

In FIG. 6, the display panel 140 of the display device 110 according to an embodiment of the present disclosure includes the display area DA at a central portion thereof and the non-display area NDA at an edge portion thereof and surrounding the display area DA. The non-display area NDA includes first, second, third and fourth non-display areas NDA1, NDA2, NDA3 and NDA4 at left, right, upper and lower sides, respectively, of the display area DA.

The first and second gate driving units 130 and 135 are disposed in the first and second non-display areas NDA1 and NDA2, respectively.

In FIG. 7A, the first non-display area NDA1 includes the stage circuit block Bsc and the low-level voltage block Blv. A first trench TRE1 extending along a vertical direction (a direction parallel to the data line DL) is disposed between the stage circuit block Bsc and the low-level voltage block Blv, and a second trench TRE2 extending along the vertical direction is disposed between the low-level voltage block Blv and the display area DA.

The stage circuit block Bsc includes a plurality of transistors and a plurality of capacitors, and the low-level voltage block Blv includes a plurality of low-level power lines Lss.

The gate line GL extends along a horizontal direction from the stage circuit block Bsc to the display area DA through the first trench TRE1, the low-level voltage block Blv and the second trench TRE2.

For example, the gate line GL may be connected to a connection node between a pull up transistor and a pull-down transistor of a buffer block of the stage circuit block Bsc and the gate electrode of the switching transistor Ts of each subpixel SP1 to SP4 in the display area DA.

Since the first trench TRE1 and the second trench TRE2 are not formed in a region corresponding to the gate line GL, the first trench TRE1 and the second trench TRE2 may be divided into pieces along the vertical direction.

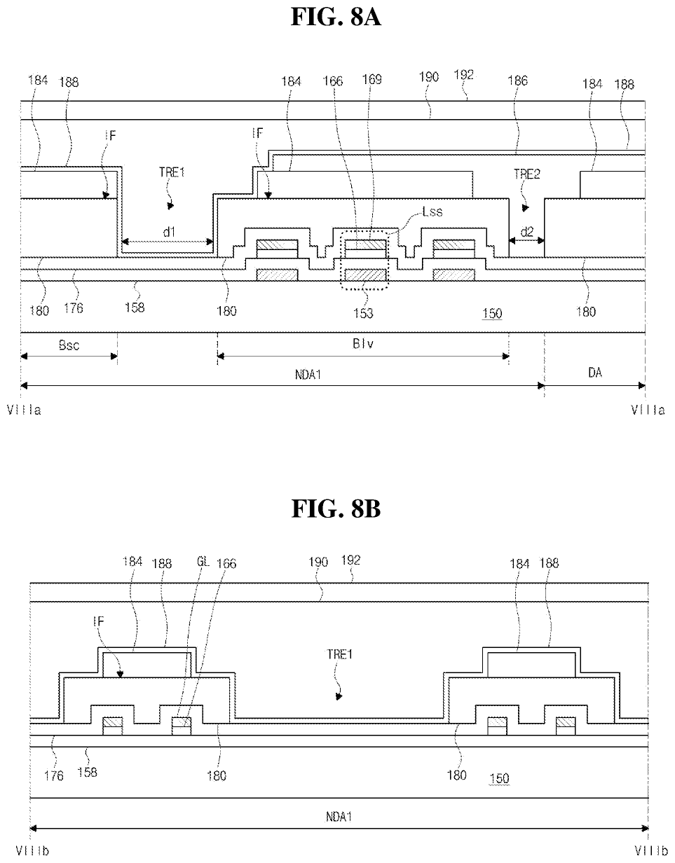

Each of the plurality of low-level power lines Lss of the low-level voltage block Blv may have a double layer of first and second line layers 153 and 169 (of FIG. 8A). Since the second line layer 169 is not formed in a region corresponding to the gate line GL, the second line layer 169 is divided into pieces along the vertical direction.

The first trench TRE1 has a first width d1, and the second trench TRE2 has a second width d2 equal to or smaller than the first width d1 (d2≤d1). For example, each of the first and second widths d1 and d2 may be within a range of about 50 μm to about 350 μm.

Although the first trench TRE1 is disposed between stage circuit block Bsc and the low level voltage block Blv and the second trench TRE2 is disposed between the low level voltage block Bsc and the display area DA in an embodiment of FIG. 7A, at least two trenches may be variously disposed between two of the clock signal block Bcl, the high level voltage block Bhv, the stage circuit block Bsc, the low level voltage block Blv and the display area DA.

The second non-display area NDA2 may have a symmetrical structure with the first non-display area NDA1. For example, the second trench TRE2, the low-level voltage block Blv, the first trench TRE1 and the stage circuit block Bsc may be sequentially disposed from a region closer to the display area DA in the second non-display area NDA2.

In FIG. 7B, a third trench TRE3 extending along a horizontal direction is disposed in the fourth non-display area NDA4 adjacent to the display area DA.

The third trench TRE3 has a third width d3 equal to or greater than the first width d1 (d3≥d1). For example, third width d3 may be within a range of about 500 μm to about 1500 μm.

Although not shown, the third non-display area NDA3 may include a link block where a plurality of link lines are disposed, and at least one trench extending along the horizontal direction may be disposed between the display area DA and the link block or at an upper side of the link block.

In a plan view, one side of the first to third trenches TRE1 to TRE3 may have a straight line shape SS or an uneven shape US. Since the uneven shape US alleviates a slope of a sidewall of the first to third trenches TRE1 to TRE3 as compared with the straight line shape SS, a step coverage of the emitting layer 186 and the second electrode 188 in a subsequent process may be improved due to the uneven shape US.

A cross-sectional structure of the trench will be illustrated with reference to drawings.

FIGS. 8A and 8B are cross-sectional views taken along a line VIIIa-VIIIa and a line VIIIb-VIIIb, respectively, of FIG. 7A according to one embodiment.

In FIG. 8A, the first non-display area NDA1 of the display device 110 includes the stage circuit block Bsc and the low-level voltage block Blv. The first trench TRE1 is disposed between the stage circuit block Bsc and the low-level voltage block Blv, and the second trench TRE2 is disposed between the low-level voltage block Blv and the display area DA.

A plurality of first line layers 153 are disposed in the low-level voltage block Blv of the first non-display area NDA1 on the substrate 150, and the buffer layer 158 is disposed on the plurality of first line layers 153 over the entire substrate 150.

The plurality of first line layers 153 of the low-level voltage block Blv may have the same layer and the same material as the light shielding layer 152 of each subpixel SP1 to SP4.

The gate insulating layer 166 and the plurality of second line layers 169 are sequentially disposed on the buffer layer 158 corresponding to the plurality of first line layers 153, and the interlayer insulating layer 176 is disposed on the plurality of second line layers 169 over the entire substrate 150.

The plurality of second line layers 169 of the low-level voltage block Blv may have the same layer and the same material as the gate electrode 168 of each subpixel SP1 to SP4.

Although not shown, the plurality of first line layers 153 and the plurality of second line layers 169 are connected to each other, and a double layer of the first line layer 153 and the second line layer 169 connected to each other constitute a single low level power line Lss.

The overcoat layer 180 is disposed on the interlayer insulating layer 176 in the stage circuit block Bsc, the low-level voltage block Blv and the display area DA, the bank layer 184 is disposed on the overcoat layer 180 in the stage circuit block Bsc, the low-level voltage block Blv and the display area DA.

The overcoat layer 180 and the bank layer 184 have the first trench TRE1 of the first width d1 between the stage circuit block Bsc and the low-level voltage block Blv and the second trench TRE2 of the second width d2 between the low-level voltage block Blv and the display area DA.

The overcoat layer 180 and the bank layer 184 between the stage circuit block Bsc and the low-level voltage block Blv are selectively removed to form the first trench TRE1 exposing the interlayer insulating layer 176, and the overcoat layer 180 and the bank layer 184 between the low-level voltage block Blv and the display area DA are selectively removed to form the second trench TRE2 exposing the interlayer insulating layer 176.

As a result, an interface IF between the overcoat layer 180 and the bank layer 184 loses a continuity at the first and second trenches TRE1 and TRE2 and is divided in the non-display area NDA due to the first and second trenches TRE1 and TRE2.

The interface IF between the overcoat layer 180 and the bank layer 184 of the stage circuit block Bsc and the interface IF between the overcoat layer 180 and the bank layer 184 of the low level voltage block Blv are divided in the first trench TRE1, and the interface IF between the overcoat layer 180 and the bank layer 184 of the low level voltage block Blv and the interface IF between the overcoat layer 180 and the bank layer 184 of the display area DA are divided in the second trench TRE2.

A moisture of an exterior of the display device 110 may permeate the light emitting diode De of each subpixel SP1 to SP4 of the display area DA through the interface IF between the overcoat layer 180 and the bank layer 184.

In the display device 110 according to an embodiment of the present disclosure, since the interface IF between the overcoat layer 180 and the bank layer 184 is divided due to the first and second trenches TRE1 and TRE2 of the first non-display area NDA1, a permeation path of the external moisture to the display area DA is blocked. As a result, deterioration of a property of the light emitting diode De and a display quality of an image due to permeation of a moisture is prevented.

Similarly, a permeation path of the external moisture to the display area DA is blocked due to the trenches of the second to fourth non-display areas NDA2 to NDA4. As a result, deterioration of a property of the light emitting diode De and a display quality of an image is prevented.

In an embodiment of FIG. 8A, an end portion of the overcoat layer 180 and an end portion of the bank layer 184 of a left sidewall of the first trench TRE1 coincide with each other, and an end portion of the overcoat layer 180 and an end portion of the bank layer 184 of a right sidewall of the first trench TRE1 do not coincide with each other to have a stair shape. Further, an end portion of the overcoat layer 180 and an end portion of the bank layer 184 of left and right sidewalls of the second trench TRE2 do not coincide with each other to have a stair shape. In another embodiment, an end portion of the overcoat layer 180 and an end portion of the bank layer 184 of left and right sidewalls of the first and second trenches TRE1 and TRE2 may coincide with each other or may have a stair shape.

The emitting layer 186 is disposed on the bank layer 184 in the low-level voltage block Blv and the display area DA, and the second electrode 188 is disposed on the emitting layer 186 over the entire substrate 150.

The emitting layer 186 fills the second trench TRE2 to directly contact the overcoat layer 180 and the bank layer 184 of left and right sidewalls of the second trench TRE2 and the interlayer insulating layer 176 at a bottom of the second trench TRE2.

Although the emitting layer 186 extends from the display area DA to the low-level voltage block Blv to fill the second trench TRE2 in an embodiment of FIG. 8A, the emitting layer 186 may extend from the display area DA to the stage circuit block Bsc to fill the first and second trenches TRE1 and TRE2.

The second electrode 188 is disposed on the left and right sidewalls and the bottom of the first trench TRE1 as well as on the bank layer 184 of the stage circuit block Bsc and the low-level voltage block Blv. As a result, the second electrode 188 directly contacts the overcoat layer 180 and the bank layer 184 of the left and right sidewalls of the first trench TRE1 and the interlayer insulating layer 176 of the bottom of the first trench TRE1.

The second electrode 188 covers the interface IF between the overcoat layer 180 and the bank layer 184 of the left and right sidewalls of the first trench TRE1.

The first encapsulating layer 190 and the second encapsulating layer 192 are sequentially disposed on the second electrode 188 over the entire substrate 150.

In FIG. 8B, the first trench TRE1 extending along the vertical direction is disposed in the first non-display area NDA1 of the display device 110, and the gate line GL extends along the horizontal direction through the first trench TRE1.

The buffer layer 158 is disposed over the entire substrate 150, the gate insulating layer 166 and the plurality of gate lines GL are sequentially disposed on the buffer layer 158 in the first non-display area NDA1, and the interlayer insulating layer 176 is disposed on the plurality of gate lines GL over the entire substrate 150.

The plurality of gate lines GL of the first non-display area NDA1 may have the same layer and the same material as the gate electrode 168 of each subpixel SP1 to SP4.

Two gate lines GL of the plurality of gate lines GL separated from each other by a relatively short distance constitute a pair, and the adjacent two pairs are separated from each other by a relatively long distance.

In another embodiment, the plurality of gate lines GL may be separated from each other by an equal distance, or at least three gate lines GL of the plurality of gate lines GL are separated from each other by a relatively short distance and the adjacent two pairs are separated from each other by a relatively long distance.

The overcoat layer 180 is disposed on the interlayer insulating layer 176 corresponding to each pair of the plurality of gate lines GL, and the bank layer 184 is disposed on the overcoat layer 180 corresponding to each pair of the plurality of gate lines GL.

The overcoat layer 180 and the bank layer 184 have the first trench TRE1 between the adjacent two pairs of the plurality of gate lines GL.

The overcoat layer 180 and the bank layer 184 between the adjacent two pairs of the plurality of gate lines GL are selectively removed to form the first trench TRE1 exposing the interlayer insulating layer 176.

Although an end portion of the overcoat layer 180 and an end portion of the bank layer 184 of the left and right sidewalls of the first trench TRE1 do not coincide with each other to have a stair shape in an embodiment of FIG. 8A, an end portion of the overcoat layer 180 and an end portion of the bank layer 184 of the left and right sidewalls of the first trench TRE1 may coincide with each other in another embodiment.

The second electrode 188 is disposed on the bank layer 184 over the entire substrate 150.

The second electrode 188 is disposed on the left and right sidewalls and the bottom of the first trench TRE1 as well as on the top surface of the bank layer 184 corresponding to each pair of the plurality of gate lines GL. As a result, the second electrode 188 directly contacts the overcoat layer 180 and the bank layer 184 of the left and right sidewalls of the first trench TRE1 and directly contacts the interlayer insulating layer 176 of the bottom of the first trench TRE1.

The second electrode 188 covers the interface IF between the overcoat layer 180 and the bank layer 184 of the left and right sidewalls of the first trench TRE1.

The first encapsulating layer 190 and the second encapsulating layer 192 are sequentially disposed on the second electrode 188 over the entire substrate 150.

Consequently, in the display device 110 according to an embodiment of the present disclosure, since the interface between the overcoat layer 180 and the bank layer 184 is divided by forming the first trench TRE1 between the overcoat layer 180 and the bank layer 184 of the non-display area NDA, permeation of the external moisture to the light emitting diode De of the display area DA through the interface between the overcoat layer 180 and the bank layer 184 is reduced or minimized.

Further, since the first trench TRE1 of the overcoat layer 180 and the bank layer 184 is formed in an available space of the non-display area NDA, permeation of a moisture through the interface between the overcoat layer 180 and the bank layer 184 is reduced or minimized without a loss of an aperture ratio, and deterioration of a property of the light emitting diode De and a display quality of an image is reduced or prevented.

It will be apparent to those skilled in the art that various modifications and variation can be made in the present disclosure without departing from the scope of the disclosure. Thus, it is intended that the present disclosure cover the modifications and variations of this disclosure provided they come within the scope of the appended claims.

What is claimed is:

1. A display device, comprising:
a substrate having a display area including a subpixel and a non-display area surrounding the display area, the subpixel comprising a driving transistor and a light emitting diode;
an overcoat layer between the driving transistor and the light emitting diode; and
a bank layer on the overcoat layer,
wherein in the non-display area, at least one trench is disposed through parts of the overcoat layer and the bank layer.

2. The display device of claim 1, wherein a gate driving circuit generates a gate signal supplied to the display area, the gate driving circuit having a plurality of blocks in the non-display area, and
wherein the at least one trench is at least one of between the plurality of blocks and between one of the plurality of blocks and the display area.

3. The display device of claim 2, wherein the at least one trench includes a first trench and a second trench,
wherein the plurality of blocks include a clock signal block, a high-level voltage block, a stage circuit block and a low-level voltage block, and
wherein the first trench is between the stage circuit block and the low-level voltage block, and the second trench is between the low-level voltage block and the display area.

4. The display device of claim 3, wherein a plurality of first line layers and a plurality of second line layers on the plurality of first line layers are in the low-level voltage block between the substrate and the overcoat layer, and
wherein the plurality of first line layers and the plurality of second line layers are connected to each other to constitute a plurality of low-level power lines.

5. The display device of claim 3, wherein a gate line transmitting the gate signal extends from the stage circuit block to the display area through the first trench, the low-level voltage block and the second trench, and
wherein the first trench and second trench are divided by the gate line.

6. The display device of claim 3, wherein the gate signal includes a scan signal and a sensing signal, and the subpixel further comprises:
a switching transistor that switches according to the scan signal, the switching transistor connected to a data signal;
a storage capacitor connected to the switching transistor;
the driving transistor that switches according to a voltage of a first capacitor electrode of the storage capacitor, the driving transistor connected to a high-level voltage;
a reference transistor that switches according to the sensing signal, the reference transistor connected to the storage capacitor, the driving transistor and a reference signal; and
the light emitting diode is connected to the storage capacitor, the driving transistor, the reference transistor, and a low-level voltage.

7. The display device of claim 6, wherein at least one of the switching transistor, the driving transistor and the reference transistor is an oxide semiconductor thin film transistor.

8. The display device of claim 6, wherein the stage circuit block generates the scan signal and transmits the scan signal to the switching transistor through a gate line, and
wherein the stage circuit block generates the sensing signal and transmits the sensing signal to the reference transistor through the gate line.

9. The display device of claim 1, wherein the non-display area includes a first non-display area, a second non-display area, a third non-display area, and a fourth non-display area at left, right, upper, and lower portions of the display area, respectively, and
wherein the at least one trench is in one or more of the first non-display area, the second non-display area, the third non-display area, and the fourth non-display area.

10. The display device of claim 1, wherein an end portion of the overcoat layer and an end portion of the bank layer of a sidewall of the at least one trench coincides with each other or have a stair shape.

11. The display device of claim 1, further comprising:
a light shielding layer in the subpixel on the substrate;
a buffer layer between the light shielding layer and the driving transistor;
an interlayer insulating layer between the driving transistor and the overcoat layer; and
a first encapsulating layer and a second encapsulating layer sequentially disposed on the light emitting diode.

12. The display device of claim 11, wherein the driving transistor includes an active layer on the buffer layer corresponding to the light shielding layer, a gate insulating layer, and a gate electrode sequentially disposed on a central portion of the active layer, a source electrode contacting a first end portion of the active layer and the light shielding layer, and a drain electrode contacting a second end portion of the active layer.

13. The display device of claim 11, wherein the light emitting diode includes a first electrode on the overcoat layer and connected to a source electrode, an emitting layer on the first electrode, and a second electrode on the emitting layer, and
wherein the bank layer covers an edge portion of the first electrode, the bank layer having an opening that exposes a central portion of the first electrode.

14. The display device of claim 13, wherein the at least one trench exposes the interlayer insulating layer, and wherein the second electrode covers an interface between the overcoat layer and the bank layer of a sidewall of the at least one trench.

15. The display device of claim 1, wherein a side of the at least one trench has one of a straight line shape and an uneven shape in a plan view.

16. A display device, comprising:
a substrate having a display area and a non-display area surrounding the display area,
wherein the non-display area comprises a plurality of blocks, and a trench that is at least one of between the plurality of blocks, between one of the plurality of blocks and the display area, and in the non-display area.
